(19) United States
(12) Patent Application Publication
(10) Pub. No.: US 2025/0293506 A1
(43) Pub. Date: Sep. 18, 2025

(54) SHORT-CIRCUIT PROTECTION CIRCUIT FOR SIC MOS TRANSISTOR

(71) Applicant: Schneider Electric Industries SAS, Rueil Malmaison (FR)

(72) Inventors: Jie Huang, Shanghai (CN); Baoyun Bi, Shanghai (CN); Qilei Zhu, Shanghai (CN)

(73) Assignee: Schneider Electric Industries SAS, Rueil Malmaison (FR)

(21) Appl. No.: 19/078,569

(22) Filed: Mar. 13, 2025

(30) Foreign Application Priority Data
Mar. 18, 2024 (CN) 202420529521.5

(51) Int. Cl. H02H 3/087; H02H 1/00

(52) U.S. Cl. CPC H02H 3/087; H02H 1/0007

(57) ABSTRACT

Embodiments of the disclosure provide a short-circuit protection circuit for a SiC MOS transistor including: a state detection unit configured to generate an indication signal for indicating whether a short-circuit occurs; a driving unit connected to the SiC MOS transistor, to drive the SiC MOS transistor to be turned off in response to that the indication signal indicates that a short-circuit occurs; and a power supply voltage conversion unit, the power supply voltage conversion unit being connected to the state detection unit, to switch between a first on position and a second on position, the power supply voltage conversion unit being connected to the driving unit, to provide a first power supply voltage or a second power supply voltage to the driving unit, the driving unit being configured to provide a first driving voltage to the SiC MOS transistor and provide a second driving voltage to the SiC MOS transistor.

### CROSS-REFERENCE

The present application claims priority to Chinese Patent Application No. 202420529521.5, filed on Mar. 18, 2024 and entitled “SHORT-CIRCUIT PROTECTION CIRCUIT FOR SIC MOS TRANSISTOR”, the entirety of which is incorporated herein by reference.

### FIELD

Embodiments of the present disclosure relate to a field of electrical equipment, and more particularly, to a short-circuit protection circuit for a SiC MOS transistor.

### BACKGROUND

With development of many emerging industries, it is difficult for a conventional Si power semiconductor device to meet a new application of high efficiency and high power density. A SiC metal oxide semiconductor field effect transistor (SiC MOSFET for short) has a low switching loss, a high switching frequency, a high voltage-resistant value and an excellent temperature characteristic, so that conversion efficiency, power density and stability of whole power electronic equipment are greatly improved. However, compared with a Si power semiconductor device, short-circuit bearing capacity of the SiC MOSFET is relatively weak. Therefore, how to improve anti-short-circuit capability of the SiC MOSFET becomes a problem worthy of attention.

### SUMMARY

An object of the present disclosure is to provide a short-circuit protection circuit for a SiC MOS transistor to at least partially solve above described problems.

In a first aspect of the present disclosure, a short-circuit protection circuit for a SiC MOS transistor is provided, including: a state detection unit connected to a drain of the SiC MOS transistor and a power supply, and configured to generate an indication signal for indicating whether a short-circuit occurs in the power supply; a driving unit, a first input end of the driving unit being connected to a first output end of the state detection unit, and an output end of the driving unit being connected to a gate of the SiC MOS transistor, to drive the SiC MOS transistor to be turned off in response to that the indication signal indicates that a short-circuit occurs in the power supply; and a power supply voltage conversion unit, a first end of the power supply voltage conversion unit being connected to the state detection unit, to switch between a first on position for turning on a first power supply and a second on position for turning on a second power supply based on the indication signal, a second end of the power supply voltage conversion unit being connected to a power supply end of the driving unit, to provide a first power supply voltage of the first power supply or a second power supply voltage of the second power supply to the driving unit, voltage magnitudes of the first power supply voltage and the second power supply voltage being different, the driving unit being configured to provide a first driving voltage to the SiC MOS transistor in response to receiving the first power supply voltage, the driving unit being configured to provide the second driving voltage to the SiC MOS transistor in response to receiving the second power supply voltage, voltage magnitudes of the first driving voltage and the first power supply voltage being the same, and voltage magnitudes of the second driving voltage and the second power supply voltage being the same.

In embodiments according to the present disclosure, short-circuit detection of the power supply can be reliably performed by adopting the state detection unit, the SiC MOS transistor can be reliably driven to be turned off in response to that a short-circuit occurs in the power supply by adopting the driving unit, the first power supply voltage or the second power supply voltage can be reliably supplied to the driving unit by adopting the power supply voltage conversion unit, so that the driving unit provides the first driving voltage or the second driving voltage to the SiC MOS transistor, thereby improving anti-short-circuit capability of the SiC MOS transistor with a characteristic that anti-short-circuit time of the SiC MOS transistor are different under different driving voltages.

In some embodiments, the short-circuit protection circuit further includes a control unit, an input end of the control unit is connected to a second output end of the state detection unit, and an output end of the control unit is connected to a second input end of the driving unit, the control unit is configured to receive the indication signal and generating a turn-on control signal in response to that the indication signal indicates that a short-circuit does not occur in the power supply, so that the driving unit drives the SiC MOS transistor to be turned on under control of the turn-on control signal.

In some embodiments, the state detection unit includes a resistor and a signal generation unit, the resistor is connected between the drain of the SiC MOS transistor and the power supply, a first input end of the signal generation unit is connected to a node between the resistor and the power supply, a second input end of the signal generation unit is connected to a node between the resistor and the drain of the SiC MOS transistor, a first output end of the signal generation unit is connected to a first input end of the driving unit and a first end of the power supply voltage conversion unit, a second output end of the signal generation unit is connected to an input end of the control unit, and the signal generation unit is configured to generate the indication signal in response to that a short-circuit occurs in the power supply.

In some embodiments, the short-circuit protection circuit further includes a triode, a base of the triode is connected to the second output end of the signal generation unit, an emitter of the triode is connected to an output end of the control unit, and a collector of the triode is connected to ground; and the triode is turned on in response to that a voltage magnitude of the indication signal is greater than a predetermined threshold.

In some embodiments, a ground end of the driving unit is connected to the collector of the triode, and the driving unit is configured to drive the SiC MOS transistor to be turned off in response to that the triode is turned on.

In some embodiments, a source of the SiC MOS transistor is connected to an external load.

It should be appreciated that content described in the summary is not intended to limit critical or important features of embodiments of the present disclosure, nor is it intended to limit a scope of the disclosure. Other features of the present disclosure will be readily appreciated from following description.

### BRIEF DESCRIPTION OF THE DRAWINGS

The above and other features, advantages, and aspects of various embodiments of the present disclosure will become more apparent with reference to following detailed description taken in conjunction with drawings. In the drawings, the same or similar reference numerals represent the same or similar elements, wherein:

FIG. 1 illustrates a circuit block diagram of a short-circuit protection circuit according to an embodiment of the present disclosure.

### DETAILED DESCRIPTION

Preferred embodiments of the present disclosure will be described in more detail below with reference to drawings. While the preferred embodiments of the present disclosure are shown in the drawings, it should be understood that the present disclosure may be implemented in various forms and should not be limited to the embodiments set forth herein. Rather, these embodiments are provided to make the present disclosure more thorough and complete, and to completely convey the scope of the disclosure to those skilled in the art.

The term “including” and variations thereof, as used herein, mean open-ended including, that is, “including but not limited to.” Unless specifically stated otherwise, the term “or” means “and/or.” The term “based on” means “based at least in part on.” The term “another embodiment” means “at least one further embodiment.” The terms “first,” “second,” and the like may refer to different or identical objects.

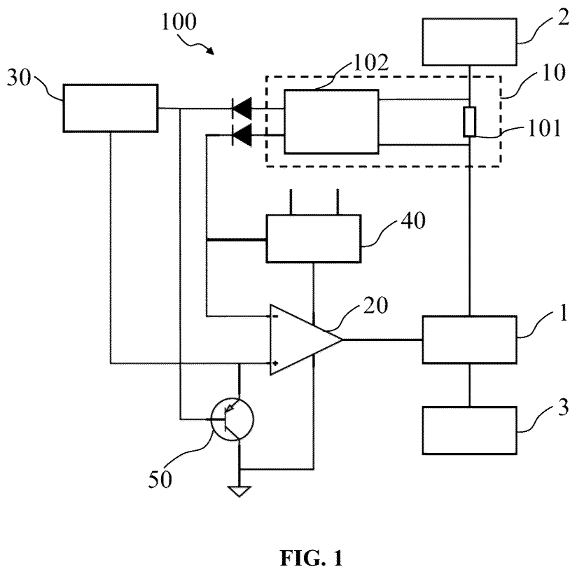

As described above, compared with the silicon power semiconductor device, the short-circuit bearing capacity of the SiC MOSFET is relatively weak. Therefore, how to improve the anti-short-circuit capability of the SiC MOSFET becomes a problem worthy of attention. Embodiments of the present disclosure provide a short-circuit protection circuit for a SiC MOS transistor, short-circuit detection of a power supply can be reliably performed by adopting the state detection unit, the SiC MOS transistor can be reliably driven to be turned off in response to that a short-circuit occurs in the power supply by adopting a driving unit, a first power supply voltage or a second power supply voltage can be reliably supplied to the driving unit by adopting the power supply voltage conversion unit, so that the driving unit provides the first driving voltage or the second driving voltage to the SiC MOS transistor, thereby improving the anti-short-circuit capability of the SiC MOS transistor with a characteristic that anti-short-circuit time of the SiC MOS transistor are different under different driving voltages. Hereinafter, a principle of the present disclosure will be described in conjunction with FIG. 1.

FIG. 1 illustrates a circuit block diagram of a short-circuit protection circuit 100 according to an embodiment of the present disclosure. As shown in FIG. 1, the short-circuit protection circuit 100 generally includes a state detection unit 10, a driving unit 20, and a power supply voltage conversion unit 40. The state detection unit 10 is connected to a drain of a SiC MOS transistor 1 and a power supply 2. The state detection unit 10 is configured to generate an indication signal for indicating whether a short-circuit occurs in the power supply 2. A first input end of the driving unit 20 is connected to a first output end of the state detection unit 10, and an output end of the driving unit 20 is connected to a gate of the SiC MOS transistor 1. A source of the SiC MOS transistor 1 is connected to an external load 3. The driving unit 20 is configured to receive an indication signal and driving the SiC MOS transistor 1 to turn off in response to that the indication signal indicates a short-circuit occurs in the power supply 2. A first end of the power supply voltage conversion unit 40 is connected to the state detection unit 10. The power supply voltage conversion unit 40 is configured to switch between a first on position for turning on a first power supply and a second on position for turning on a second power supply based on the indication signal, a second end of the power supply voltage conversion unit 40 is connected to a power supply end of the driving unit 20, to provide a first power supply voltage of the first power supply or a second power supply voltage of the second power supply to the driving unit. Voltage magnitudes of the first power supply voltage and the second power supply voltage are different. The driving unit 20 is configured to provide a first driving voltage to the SiC MOS transistor 1 in response to receiving the first power supply voltage, the driving unit is configured to provide a second driving voltage to the SiC MOS transistor 1 in response to receiving the second power supply voltage. Voltage magnitudes of the first driving voltage and the first power supply voltage are the same, and Voltage magnitudes of the second driving voltage and the second power supply voltage are the same.

In an embodiment, as shown in FIG. 1, the short-circuit protection circuit 100 may further include a control unit 30. An input end of the control unit 30 is connected to a second output end of the state detection unit 10, and an output end of the control unit 30 is connected to a second input end of the driving unit 20. The control unit 30 is configured to receive the indication signal and generating a turn-on control signal in response to that the indication signal indicates that a short-circuit does not occur in the power supply 2, so that the driving unit 20 drives the SiC MOS transistors 1 to be turned on under control of the turn-on control signal. In an embodiment, the control unit 30 is a microcontroller unit (MCU). The control unit 30 may determine whether the short-circuit occurs in the power supply 2 based on a voltage magnitude of the indication signal, and send a turn-on control signal to the driving unit 20 in response to that the voltage magnitude of the indication signal does not exceed a predetermined threshold, to control the driving unit 20 to drive the SiC MOS transistor 1 to be turned on. It should be appreciated that, based on teaching provided by the present disclosure, those skilled in the art may conceive other types of control units to implement foregoing functions, and these implementations all fall within the scope of the present disclosure.

In an embodiment, as shown in FIG. 1, the driving unit 20 may be an operational amplifier. An inverting input end of the operational amplifier may be connected to the first output end of the state detection unit 10. A non-inverting input end of the operational amplifier may be connected to the output end of the control unit 30. A power supply end of the operational amplifier may be connected to a second end of the power supply voltage conversion unit 40. An output end of the operational amplifier may be connected to a gate of the SiC MOS transistor 1. In response to that the non-inverting input end of the operational amplifier receives the turn-on control signal, the operational amplifier can drive the SiC MOS transistor 1 to be turned on, and a voltage magnitude of a driving voltage for driving the SiC MOS transistor 1 to be turned on is equal to a voltage magnitude of a power supply voltage received by the power supply end at this time. The output end of the operational amplifier outputs the first driving voltage in response to that the power supply end of the operational amplifier receives the first power supply voltage of the first power supply. The output end of the operational amplifier outputs the second driving voltage in response to that the power supply end of the operational amplifier receives the second power supply voltage of the second power supply.

In an embodiment, one of the first power supply and the second power supply is used as a common power supply when the SiC MOS transistor 1 operates normally, and the other power supply is used as a protection power supply when short-circuit occurs. A voltage magnitude of a power supply voltage of the common power supply is relatively large, and a voltage magnitude of a power supply voltage of the protection power supply is relatively small. For example, the voltage magnitude of the power supply voltage of the common power supply may be 18V, and the voltage magnitude of the power supply voltage of the protection power supply may be 15V. As described above, the voltage magnitude of the driving voltage output by the output end of the operational amplifier is equal to the voltage magnitude of the supply voltage received by the supply end of the operational amplifier. Taking the first power supply as the common power supply and the second power supply as the protection power supply as an example, when the SiC MOS transistor 1 operates normally, the power supply voltage conversion unit 40 controls t the first power supply to be turned on, when the short-circuit occurs in the power supply 2, the power supply voltage conversion unit 40 controls the second power supply to be turned on, so that the driving voltage of the SiC MOS transistor 1 is converted from the first driving voltage into the second driving voltage. At this time, the indication signal received by the inverting input end of the operational amplifier is converted from a low level signal into a high level signal, so that the operational amplifier drives the SiC MOS transistor 1 to be turned off. In this way, reliability of the short-circuit protection circuit 100 can be improved by with a characteristic that the anti-short-circuit capability of the SiC MOS transistor 1 is high under a low driving voltage. In an embodiment, the power supply voltage conversion unit 40 adopts a power supply conversion switch. It should be appreciated that, based on the teaching provided by the present disclosure, those skilled in the art may conceive other types of driving units and power supply voltage conversion units to implement the foregoing functions, and these implementations all fall within the scope of the present disclosure.

In an embodiment, as shown in FIG. 1, the state detection unit 10 includes a resistor 101 and a signal generation unit 102. The resistor 101 is connected between the drain of the SiC MOS transistor 1 and the power supply 2. A first input end of the signal generation unit 102 is connected to a node between the resistor 101 and the power supply 2. A second input end of the signal generation unit 102 is connected to a node between the resistor 101 and the drain of the SiC MOS transistor 1. A first output end of the signal generation unit 102 is connected to a first input end of the driving unit 20 and a first end of the power supply voltage conversion unit 40, a second output end of the signal generation unit 102 is connected to an input end of the control unit 30, and the signal generation unit 102 is configured to generate the indication signal in response to that the short-circuit occurs in the power supply 2. In an embodiment, the signal generation unit 102 may be an operational amplifier. The voltage magnitude of the indication signal may be adjusted by adjusting parameters of the operational amplifier and the resistor 101, to meet operation requirements of the control unit 30. It should be appreciated that, based on the teaching provided by the present disclosure, those skilled in the art may conceive other types of signal generation units to implement foregoing functions, and these implementations all fall within the scope of the present disclosure.

With continued reference to FIG. 1, in an embodiment, the short-circuit protection circuit 100 may further include a triode 50. A base of the triode 50 is connected to the second output end of the signal generation unit 102. An emitter of the triode 50 is connected to an output end of the control unit 30. A collector of the triode 50 is connected to ground. The collector of the transistor 50 is connected to a ground end of the driving unit 20. In response to that the short-circuit occurs in the power supply 2, the voltage magnitude of the indication signal is sharply increased, and the transistor 50 is turned on in response to that the voltage magnitude of the indication signal is greater than the predetermined threshold. In response to that the triode 50 is turned on, the turn-on control signal provided by the control unit 30 can be converted from a high-level signal to a low-level signal, so that the driving unit 20 drives the SiC MOS transistor 1 to be turned off. In this way, on the basis that the indication signal directly controls the driving unit 20 to turn off the SiC MOS transistor 1, it is further ensured that the SiC MOS transistor 1 can be smoothly turned off. In response to that the short-circuit occurs in a circuit, stability of the short-circuit protection circuit 100 is improved. It should be appreciated that, based on the teaching provided by the present disclosure, those skilled in the art may conceive other types of electrical devices to implement foregoing functions, and these implementations all fall within the scope of the present disclosure.

Various embodiments of the present disclosure have been described above, which are exemplary, not exhaustive, and are not limited to disclosed embodiments. Many modifications and variations will be apparent to those of ordinary skill in the art without departing from the scope and spirit of the illustrated embodiments. Selection of terms used herein is intended to best explain the principles of the embodiments, practical application or technological improvements in the marketplace, or to enable others of ordinary skill in the art to understand the embodiments disclosed herein.

What is claimed is:

1. A short-circuit protection circuit for a SiC MOS transistor, comprising:
a state detection unit connected to a drain of the SiC MOS transistor and a power supply, and configured to generate an indication signal for indicating whether a short-circuit occurs in the power supply;
a driving unit, a first input end of the driving unit being connected to a first output end of the state detection unit, and an output end of the driving unit being connected to a gate of the SiC MOS transistor, to drive the SiC MOS transistor to be turned off in response to that the indication signal indicates that a short-circuit occurs in the power supply; and
a power supply voltage conversion unit, a first end of the power supply voltage conversion unit being connected to the state detection unit, to switch between a first on position for turning on a first power supply and a second on position for turning on a second power supply based on the indication signal, a second end of the power supply voltage conversion unit being connected to a power supply end of the driving unit, to provide a first power supply voltage of the first power supply or a second power supply voltage of the second power supply to the driving unit, voltage magnitudes of the first power supply voltage and the second power supply voltage being different, the driving unit being configured to provide a first driving voltage to the SiC MOS transistor in response to receiving the first power supply voltage, the driving unit being configured to provide a second driving voltage to the SiC MOS transistor in response to receiving the second power supply voltage, voltage magnitudes of the first driving voltage and the first power supply voltage being the same, and voltage magnitudes of the second driving voltage and the second power supply voltage being the same.

2. The short-circuit protection circuit of claim 1, wherein the short-circuit protection circuit further comprises a control unit, an input end of the control unit is connected to a second output end of the state detection unit, and an output end of the control unit is connected to a second input end of the driving unit, the control unit is configured to receive the indication signal and generating a turn-on control signal in response to that the indication signal indicates that a short-circuit does not occur in the power supply, so that the driving unit drives the SiC MOS transistor to be turned on under control of the turn-on control signal.

3. The short-circuit protection circuit of claim 2, wherein the state detection unit comprises a resistor and a signal generation unit, the resistor is connected between the drain of the SiC MOS transistor and the power supply, a first input end of the signal generation unit is connected to a node between the resistor and the power supply, a second input end of the signal generation unit is connected to a node between the resistor and the drain of the SiC MOS transistor, a first output end of the signal generation unit is connected to a first input end of the driving unit and a first end of the power supply voltage conversion unit, a second output end of the signal generation unit is connected to an input end of the control unit, and the signal generation unit is configured to generate the indication signal in response to that a short-circuit occurs in the power supply.

4. The short-circuit protection circuit of claim 3, wherein the short-circuit protection circuit further comprises a triode, a base of the triode is connected to the second output end of the signal generation unit, an emitter of the triode is connected to an output end of the control unit, and a collector of the triode is connected to ground, and the triode is turned on in response to that a voltage magnitude of the indication signal is greater than a predetermined threshold.

5. The short-circuit protection circuit of claim 4, wherein a ground end of the driving unit is connected to the collector of the triode, and the driving unit is configured to drive the SiC MOS transistor to be turned off in response to that the triode is turned on.

6. The short-circuit protection circuit of claim 1, wherein a source of the SiC MOS transistor is connected to an external load.
